(19) United States
(12) Patent Application Publication
(10) Pub. No.: US 2015/0179657 A1
(43) Pub. Date: Jun. 25, 2015

(54) SEMICONDUCTOR STORAGE DEVICE

(71) Applicant: KABUSHIKI KAISHA TOSHIBA, Tokyo (JP)

(72) Inventor: Seiji INUMIYA, Yokkaichi (JP)

(21) Appl. No.: 14/481,297

(22) Filed: Sep. 9, 2014

Related U.S. Application Data
(60) Provisional application No. 61/920,601, filed on Dec. 24, 2013.

(51) Int. Cl. H01L 27/115; H01L 43/10; H01L 43/02

(52) U.S. Cl. CPC H01L 27/11502; H01L 43/02; H01L 43/10

(57) ABSTRACT

A semiconductor storage device is provided with a semiconductor channel region; a first insulating layer including an oxide film disposed in contact with the semiconductor channel region, an yttrium oxide containing film disposed on the oxide film, and a hafnium oxide film having an orthorhombic phase III structure disposed on the yttrium oxide containing film; and a control electrode disposed on the first insulating layer.

### CROSS-REFERENCE TO RELATED APPLICATION(S)

This application is based upon and claims the benefit of priority from U.S. Provisional Patent Application No. 61/920,601, filed on Nov. 13, 2013 the entire contents of which are incorporated herein by reference.

### FIELD

Embodiments disclosed herein generally relate to semiconductor storage device.

BACKGROUND

In addition to a floating-electrode type flash memory device allowing nonvolatile storage of information by accumulating charge, for example, in a floating electrode, a ferroelectric memory utilizing ferroelectric materials is being developed as, for example, a volume semiconductor storage device. The ferroelectric memory is categorized into a capacitor type and a transistor type. The capacitor type comprises a combination of a transistor and a capacitor. The transistor type utilizes ferroelectric materials in a gate insulating film of a transistor.

Among these types of semiconductor storage devices, applications utilizing a ferroelectric phase of a hafnium oxide (film) containing silicon additive (Si:HfO₂) is becoming popular. In one example, a hafnium oxide (film) containing silicon additives is formed above a semiconductor substrate via a gate insulating film and a control electrode is formed above the hafnium oxide (film) containing silicon additives. In such types of semiconductor devices, information is written into/erased from the memory cell by reversing, in the up and down direction, the polarization in the ferroelectric film in response to the voltage applied to the control gate.

### BRIEF DESCRIPTION OF THE DRAWINGS

FIG. 1A pertains to a first embodiment and is one schematic example of a circuit diagram partially illustrating an electrical configuration of a memory-cell region.

FIG. 1B pertains to the first embodiment and is one schematic example of a plan view partially illustrating a planar layout of the memory-cell region.

FIG. 2A pertains to the first embodiment and is one schematic example of a vertical cross-sectional side view of structures of a semiconductor storage device (a schematic vertical cross-sectional side view taken along line 2A-2A of FIG. 1B).

FIG. 2B pertains to the first embodiment and is one schematic example of a vertical cross-sectional side view of structures of a semiconductor storage device (a schematic vertical cross-sectional side view taken along line 2B-2B of FIG. 1B).

FIG. 2C is one example of a perspective view schematically illustrating an example of an orthorhombic phase III crystal structure.

FIGS. 3A, 4A, 5A, 6A, 7A, 8A, 9A, and 10A pertain to the first embodiment and are examples of vertical cross-sectional side views schematically illustrating one phase of a manufacturing process flow of the semiconductor storage device (schematic vertical cross-sectional side views taken along line 2A-2A of FIG. 1B: part 1 to part 8)

FIGS. 3B, 4B, 5B, 6B, 7B, 8B, 9B, and 10B pertain to the first embodiment and are examples of vertical cross-sectional side views schematically illustrating one phase of a manufacturing process flow of the semiconductor storage device (schematic vertical cross-sectional side views taken along line 2B-2B of FIG. 1B: part 1 to part 8).

FIG. 11 pertains to the first embodiment and a second embodiment and is one schematic example of a band diagram illustrating a vicinity of an interface between a silicon oxide film and a silicon oxide film containing hafnium additives.

FIG. 12 pertains to the second embodiment and is one schematic example of a circuit diagram partially illustrating an electrical configuration of a three-dimensional memory structure.

FIG. 13 pertains to the second embodiment and is one example of a perspective view schematically illustrating the three-dimensional memory structure.

FIG. 14 pertains to the second embodiment and is one example of a vertical cross-sectional side view schematically illustrating the three-dimensional memory structure.

FIGS. 15 to 31 pertain to the second embodiment and are examples of vertical cross-sectional side views schematically illustrating one phase of a manufacturing process flow of the three-dimensional memory structure (part 1 to part 17).

FIG. 32 pertains to a third embodiment and is an example of a vertical cross-sectional side view schematically illustrating one phase of a manufacturing process flow of the three-dimensional memory structure.

### DETAILED DESCRIPTION

An embodiment of a semiconductor storage device is provided with a semiconductor channel region; a first insulating layer including an oxide film disposed in contact with the semiconductor channel region, an yttrium oxide containing film disposed on the oxide film, and a hafnium oxide film having an orthorhombic phase III structure disposed on the yttrium oxide containing film; and a control electrode disposed on the first insulating layer.

An embodiment of a semiconductor storage device is provided with a semiconductor channel region; a first insulating layer including an oxide film disposed in contact with the semiconductor channel region, an yttrium, oxide containing film disposed on the oxide film, and a hafnium oxide film disposed on the yttrium oxide containing film; and a control electrode disposed on the first insulating layer.

An embodiment of a semiconductor storage device is provided with a semiconductor channel region; a first insulating layer including an oxide film disposed in contact with the semiconductor channel region, an yttrium oxide containing film disposed on the oxide film, and a hafnium oxide film disposed on the yttrium oxide containing film; and a control electrode disposed on the first insulating layer, the hafnium oxide film being configured to satisfy at least either of: including silicon (Si) elements such that an atomicity ratio satisfies 0.02≦Si/(Hf+Si)≦0.05, including yttrium (Y) elements such that an atomicity ratio satisfies 0.001≦Y/(Hf+Y)≦0.06, including aluminum (Al) elements such that an atomicity ratio satisfies 0.04≦Al/(Hf+Al)≦0.1, and including zirconium (Zr) elements such that an atomicity ratio satisfies 0.3≦Zr/(Hf+Zr)≦0.7.

Embodiments of a semiconductor storage device and a manufacturing method of the same are described hereinafter with reference to the drawings. In the drawings referred to in the following description, elements that are identical or similar are identified with identical or similar reference symbols. The drawings are schematic and thus, are not necessarily consistent with the actual correlation of thickness to planar dimensions and the actual thickness ratios between each of the layers. Further, directional terms such as up, down, left, and right are used in a relative context with an assumption that the surface, on which circuitry is formed, of the later described semiconductor substrate faces up. Thus, the directional terms do not necessarily correspond to the directions based on gravitational acceleration. Further, convenience of explanation, directional terms such as up, down, left, right, high and low, as well as deep and shallow for describing the trenches are used in a relative context with respect to a rear side of the later described semiconductor substrate.

In the following description, XYZ orthogonal coordinate system is used for convenience of explanation. In the coordinate system, the X direction and the Y direction each indicates a direction parallel to the surface of a semiconductor substrate and crosses with one another. The direction crossing with both the X and the Y direction is referred to as the Z direction.

The first embodiment is described based on a cell-unit structure for a planar-type ferroelectric memory.

### First Embodiment

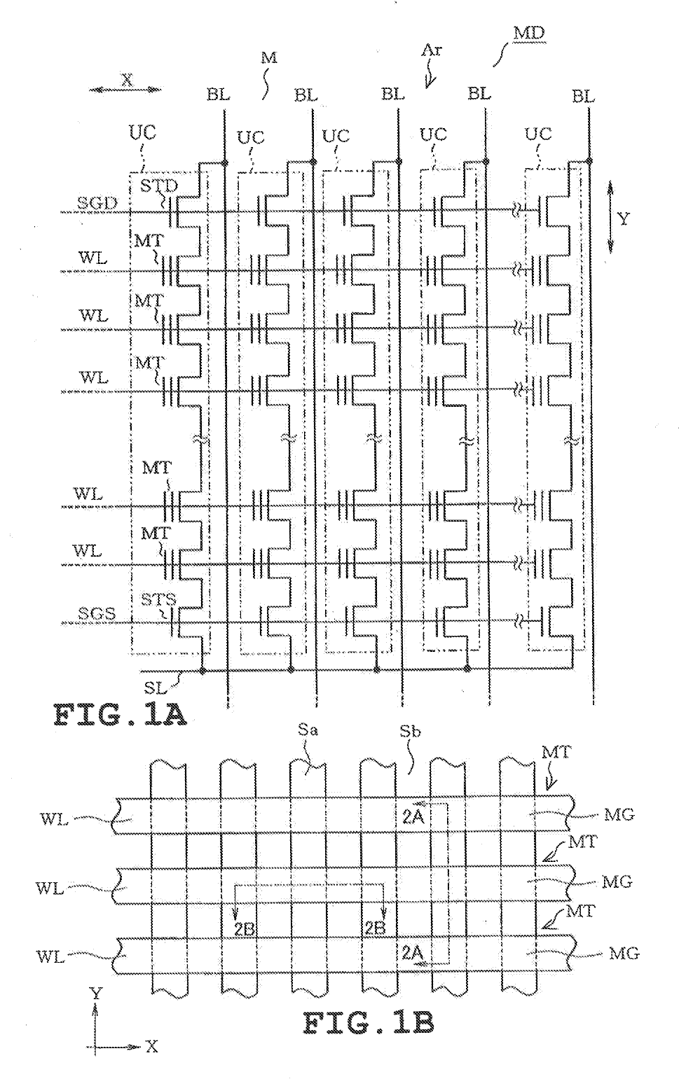

FIGS. 1A to 11 illustrate a first embodiment. In the first embodiment, ferroelectric memory is applied to each of the memory cells of a planar-type NAND flash memory device. FIG. 1A illustrates one example of an electrical configuration of the planar-type NAND flash memory device. FIG. 1B is one example of a schematic plan view partially illustrating the layout of the memory cell.

Flash memory device MD, which is one example of a nonvolatile semiconductor storage device, is provided with memory-cell array Ar including multiplicity of cell units UC arranged in a matrix. The cell units UC are aligned in the X direction within memory-cell array Ar. Though FIG. 1A only illustrates a single block, multiple blocks are aligned in the Y direction in the actual structure with each block being configured by a cell-unit group containing multiple cell units 130.

Each cell unit UC is provided with a couple of select transistors STD and STS and multiple (64 for example) memory cells MT. Memory cells MT are series connected between select transistors STD and STS and form a cell string. Each of memory cells MT described in the embodiments serves as a polarized nonvolatile memory cell. For convenience of explanation, each polarized nonvolatile memory cell is represented by the reference symbol MT which is identical to the reference symbol for the floating-gate type nonvolatile memory cell.

Either of the drain/source of select transistor STD is connected to bit line BL and the remaining other of the drain/source of select transistor STD is connected to either of the source/drain of memory cell MT disposed at one end of the cell string. The other end of the cell string is connected to the drain/source of select transistor STS and the remaining other of the drain/source of select transistor STS is connected to source line SL.

Further, as illustrated in FIG. 1B, element regions Sa of memory cells MT are formed so as to extend in the Y direction and spaced from one another in the X direction. These element regions Sc are isolated from one another by element isolation regions Sb. Memory cells MT of multiple cell units UC are interconnected in the X direction by a common word line WL.

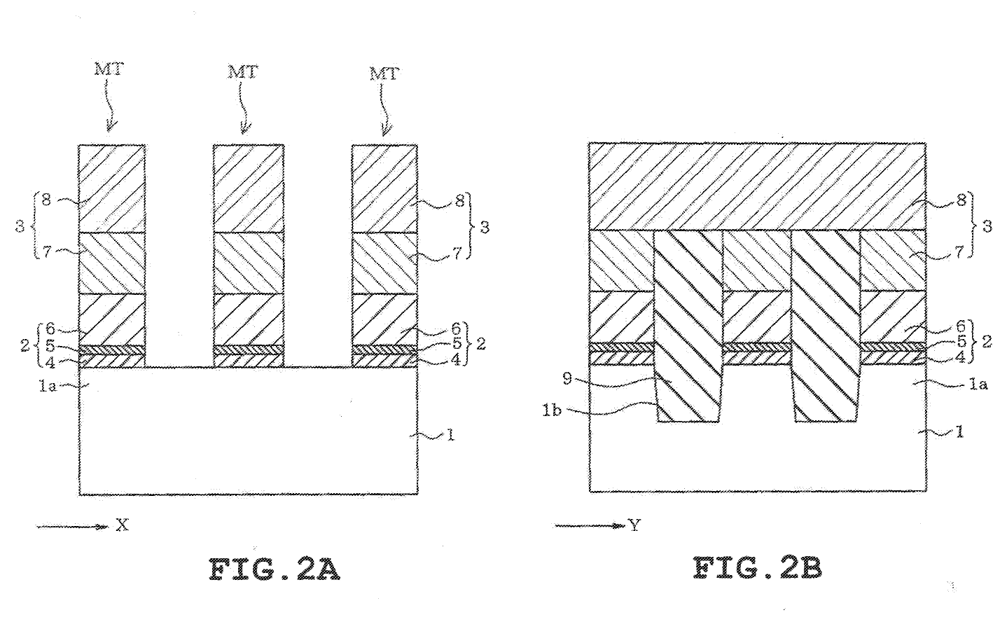

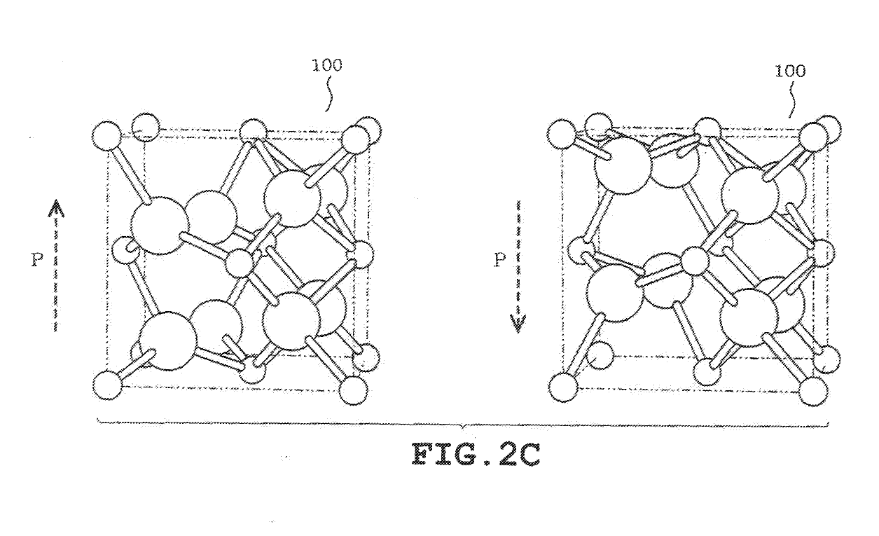

FIG. 2A schematically illustrates a cross-sectional structure of the planar-type NAND cell string taken along the length direction of the channel region at line 2A-2A of FIG. 1B. FIG. 2B schematically illustrates a cross-sectional structure of the NAND cell string taken along the width direction of the channel region at line 2B-2B of FIG. 1B.

The schematic cross section of FIG. 2A illustrates an example in which memory cells MT are disposed next to one another above semiconductor substrate 1 (a p-type monocrystal silicon substrate for example). Memory cells MT are each provided with control electrode 3 disposed above semiconductor channel region 1a of semiconductor substrate 1 via gate insulating layer 2. Gate insulating layer 2 comprises a stack of oxide film 4, yttrium oxide film 5, and hafnium oxide film 6, and serves as a first insulating layer. The surface layer of semiconductor substrate 1 located immediately below gate insulating layer 2 serves as semiconductor channel region 1a.

Oxide film 4 is formed on semiconductor substrate 1 so as to contact the upper surface of semiconductor substrate 1. The thickness of oxide film 4 ranges approximately from 0.3 nm to 2.0 nm and may be 1 nm thick for example. Yttrium oxide film 5 is formed on oxide film 4 so as to contact the upper surface of oxide film 4. The thickness of yttrium oxide film 5 ranges approximately from 0.1 nm to 0.5 nm and may be 0.3 nm thick for example. In the first embodiment, hafnium oxide film 6 contains silicon (Si) additives for example. Hafnium oxide film 6 is formed on yttrium oxide film 5 so as to contact the upper surface of yttrium oxide film 5. The thickness of hafnium oxide film 6 ranges approximately from 5 nm to 20 nm and may be 10 nm thick for example.

Control electrode 3 is configured by a stack of barrier metal film 7 such as a titanium nitride (TiN) and metal film 8 such as tungsten. Barrier metal film 7 is formed on hafnium oxide film 6 so as to contact the upper surface of hafnium oxide film 6. The thickness of barrier metal film 7 ranges approximately from 3 nm to 20 nm and may be 10 nm thick for example. Metal film 8 is formed on harrier metal film 7 so as to contact the upper surface of barrier metal film 7.

In the cross section illustrated in FIG. 2B, element isolation films 9, projecting out of semiconductor substrate 1, are disposed with a predetermined spacing between one another in the Y direction. Gate insulating layers 2 as well as barrier metal films 7 are electrically isolated from one another in the Y direction by trenches 1b. Memory cells MT are interconnected in the Y direction by metal film 8 serving as control electrode 3.

Gate insulating layer 2 of memory cell MT stores information by utilizing its polarization properties. Considering such memory properties, atomicity ratio of silicon (Si) and hafnium (Hf) in hafnium oxide film 6 containing silicon additive preferably satisfies 0.02≦Si/(Hf+Si)≦0.05.

As illustrated in FIG. 2C, the crystal structure of hafnium oxide film 6 containing silicon additive is preferably orthorhombic phase III. The orthorhombic phase III crystal structure belongs to Pbc21 space group.

Further, the property required for hafnium oxide film 6 containing silicon additive is ferroelectricity. The atomicity of silicon (Si) and atomicity of hafnium (Hf) can be measured by XPS, atom probe, or the like. It has been found by the inventor that the orthorhombic phase III crystal structure exhibits ferroelectricity.

In polarized nonvolatile memory cell MT, the change, in the forward direction/reverse direction, of polarity of electric field given between control electrode 3 and semiconductor channel region 1a modifies the crystal structure of hafnium oxide film 6. As a result, hafnium oxide film 6 becomes polarized (refer to the modification of crystal 100 illustrated in FIG. 2C).

In a ferroelectric crystal described above, the amount of polarization varies with hysteresis characteristics depending upon externally applied voltage. Thus, in memory cell MT provided with such crystals, the polarization remains even when externally given electric field is no longer applied. As a result, two polarized states can occur at two stabilization points of a hysteresis loop as shown in FIG. 2C. Thus, the ferroelectric crystal described, above is capable of a nonvolatile storage of multiple (two for example) information (“0” and “1” for example).

Further, gate insulating layer 2 disposed between memory-cells MT adjacent in the X direction may be divided as illustrated for example in FIG. 2A or structurally connected between memory cells MT adjacent in the X direction. Gate insulating layer 2 may be configured not to exhibit ferroelectricity by controlling the atomicity ratio of hafnium oxide film 6 containing silicon additive to exhibit 0.02>Si/(Hf+Si) or Si/(Hf+Si)>0.05. Thus, it is possible to prevent memory malfunctioning originating from the polarization of gate insulating layer 2 located between the adjacent memory cells MT caused by electric field leakage even when gate insulating layer 2 between the adjacent memory cells MT are connected.

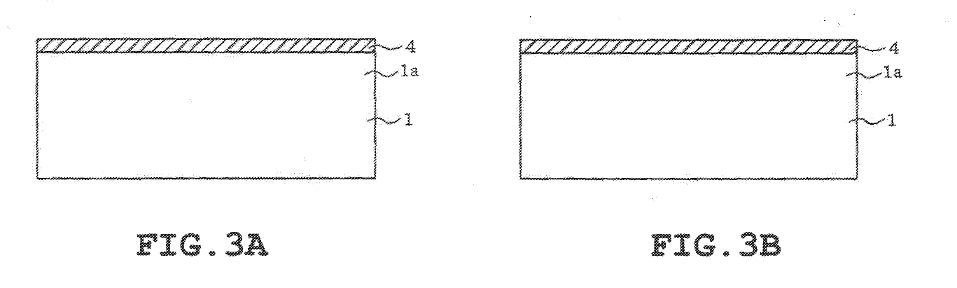

One example of a manufacturing process flow of a first embodiment of planar ferroelectric memory will be described with reference to FIGS. 3A to 10B. FIGS. 3A to 10A suffixed by “A” schematically illustrate one phase of a manufacturing process flow of memory cell MT taken along line 2A-2A of FIG. 1B. FIGS. 3B to 10B suffixed by “B” schematically illustrate one phase of a manufacturing process flow of memory cell MT taken along line 2B-2B of FIG. 1B. The following description will focus on the features of the present embodiment. However, process steps that are required for implementation or that are known may be further incorporated. Further, the discussed process steps may be rearranged if practicable.

As illustrated in FIG. 3A and FIG. 3B, oxide film 4 having a thickness of approximately 1 nm for example is formed above the upper surface of a region serving as semiconductor channel region la by thermal oxidation.

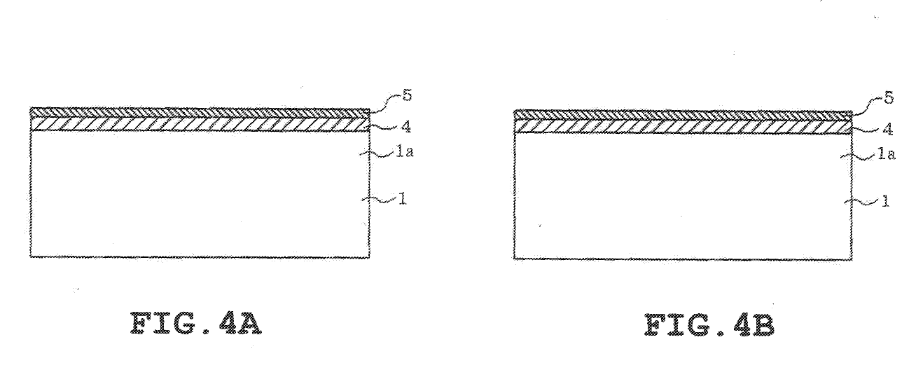

As illustrated in FIGS. 4A and 4B, yttrium oxide film 5 having a thickness of 0.3 nm for example is formed above the upper surface of oxide film as by ALD (Atomic Layer Deposition).

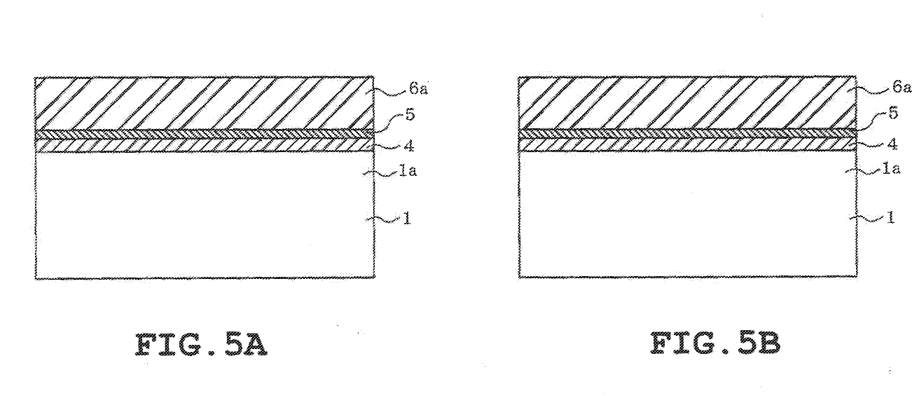

As illustrated in FIGS. 5A and 5B, hafnium oxide film 6a having a thickness ranging approximately from 5 nm to 20 nm is formed for example by ALD (Atomic layer Deposition) above the upper surface of yttrium oxide film 5. In one example, hafnium oxide film 6a is 10 nm thick. Amorphous silicon having a thickness of 10 nm for example may be added to hafnium oxide film 6A. The silicon concentration in hafnium oxide film 6A is preferably controlled so that atomicity ratio of silicon and hafnium satisfies 0.02≦Si/(Hf+Si)≦0.05.

Tris dimethyl amino silane (TrisDMAS) is preferably employed as the source of silicon and tetrakis ethylmethylamino hafnium (TEMAH) is preferably employed as the source of hafnium. Atomicity ratio may be controlled in the above described, manner through control in the number of cycles of ALD.

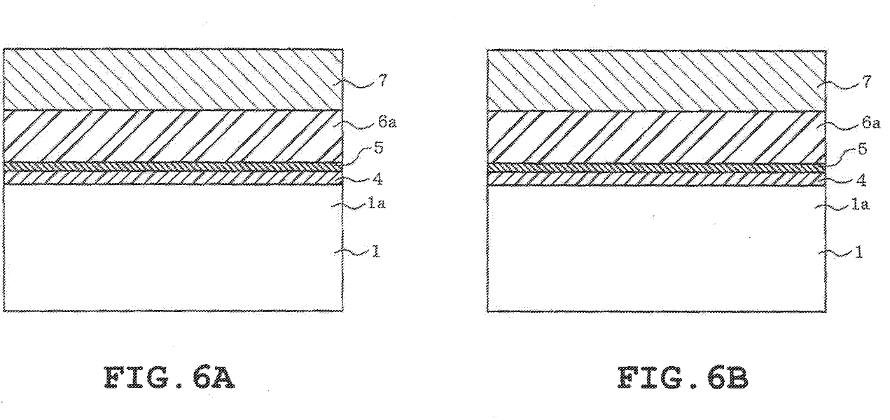

As illustrated in FIG. 6A and FIG. 6B, nitride titanium (TiN) serving as barrier metal film 7 is deposited by CVD so as to be approximately 3 nm to 20 nm thick. In one example, the titanium nitride is 10 nm thick.

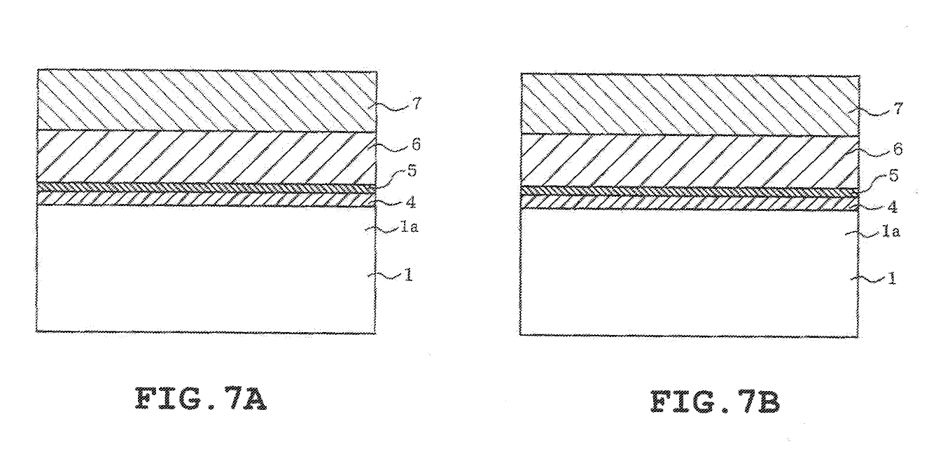

As shown in FIGS. 7A and 7B, hafnium oxide film 6a is transformed into hafnium oxide film 6 having an orthorhombic phase III crystal structure by being exposed to nitrogen ambient and being subjected to PTA (Rapid Thermal Anneal) at temperatures ranging from approximately 800 degrees Celsius to 1100 degrees Celsius. In one example, RTA is performed at 1000 degrees Celsius Hafnium oxide film 6 exhibits ferroelectricity by crystallizing in an orthorhombic phase III crystal structure. The crystallization by PTA process is not limited to the above described timing but may be performed for example after formation of other structures. The crystal structure may become cubic or monoclinic depending upon The configuration of the stacked structure of memory cell MT, the sequence of the thermal treatment process, etc. However, hafnium oxide film 6a can be transformed into hafnium oxide film 6 having an orthorhombic phase III crystal structure through appropriate adjustment of process sequence, etc.

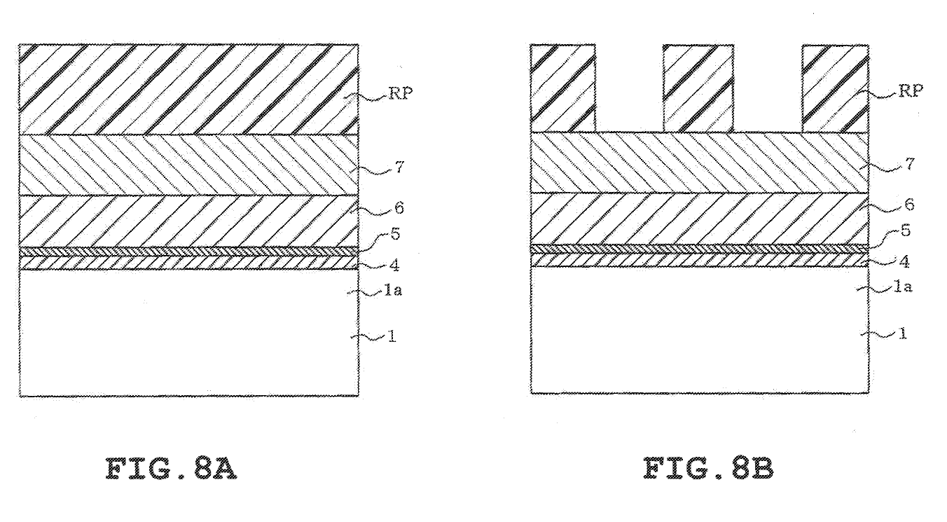

As illustrated in FIGS. 8A and 8B, resist RP is coated and patterned by lithography.

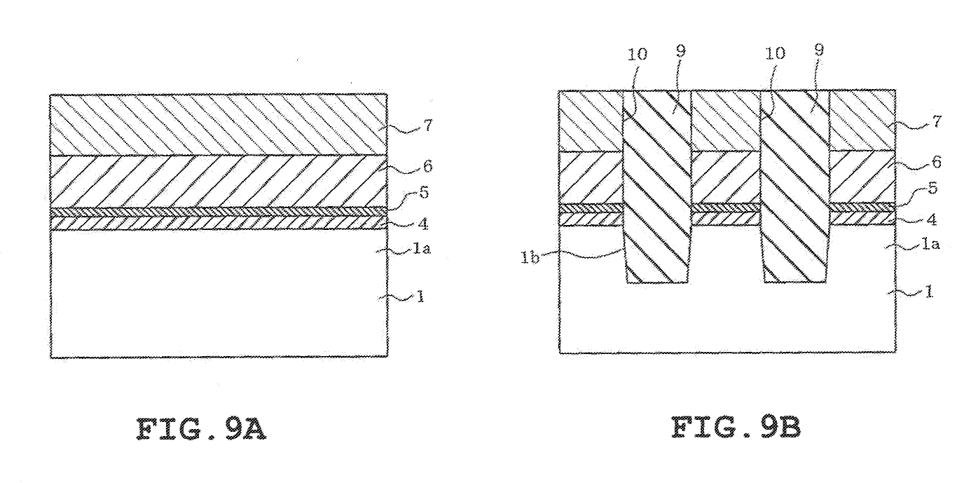

Referring to FIGS. 9A and 9B, trenches 1b for element isolation are formed by RIE. After removing resist RP, trenches 1b are filled with an insulating film 9 and the surface of barrier metal film 7 is exposed by CMP.

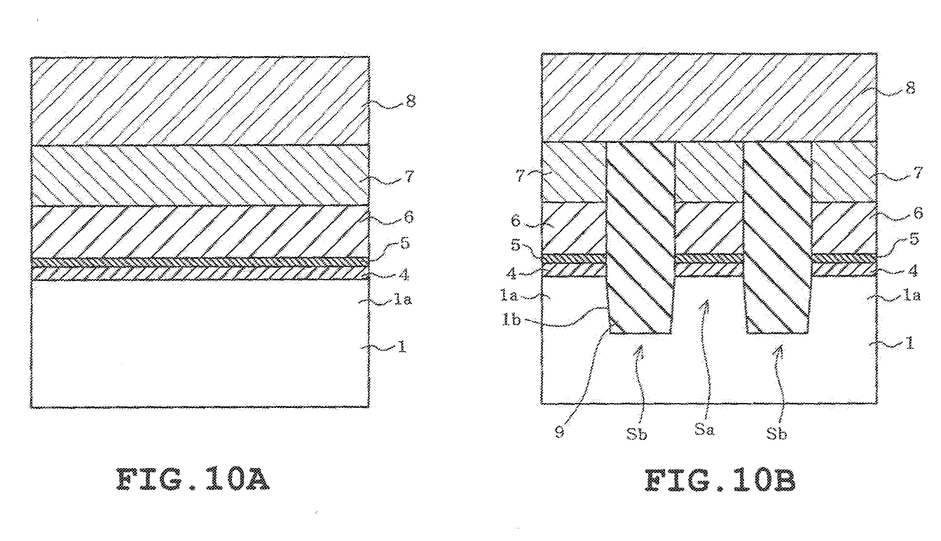

As illustrated in FIGS. 10A and 10B, tungsten, for example, serving as metal film 8 is deposited for example by PVD.

As illustrated in FIGS. 2A and 2B, gate electrode processing is carried out by lithography and RIE. Then, though neither illustrated, process steps for forming a source/drain diffusion layer, a source contact, a drain contact, upper layer wirings contacting the upper surfaces of the contacts, and the like, are performed to complete the formation of ferroelectric field-effect type memory cell MT.

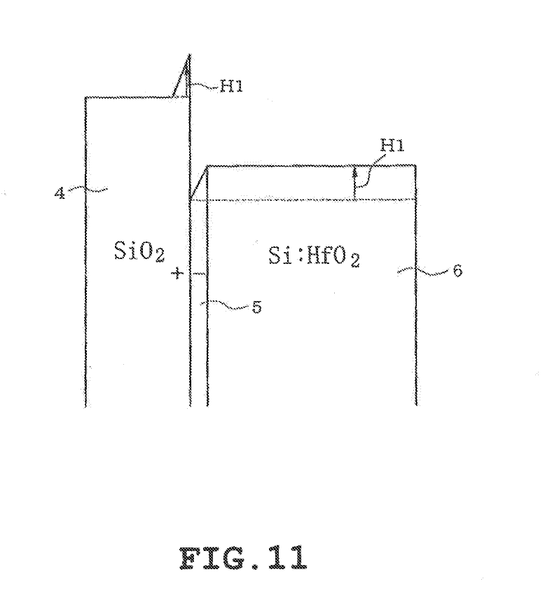

FIG. 11 schematically illustrates the energy band of the lower end portion of the conduction band. As illustrated in FIG. 11, the energy level at the lower end of the conduction band is discontinuous at both sides of the junction interface of oxide film 4 and hafnium oxide film 6. In the present embodiment, yttrium oxide film 5 is disposed between oxide film 4 and hafnium oxide film 6.

In a ferroelectric field-effect type memory cell MT fabricated in the above described manner, interface dipole is formed by the influence of yttrium oxide film 5 disposed between oxide film 4 and hafnium oxide film 6. As a result, barrier height of hafnium oxide film 6 with respect to electrons is increased (refer to reference symbol H1 indicating an arrow extending from a broken line to a solid line). Thus, it is possible to reduce leakage current flowing through gate insulating layer 2.

Hafnium oxide film 6 structured as orthorhombic phase III exhibits ferroelectricity. However, the crystallinity of hafnium oxide film 6 may be varied by the influence of the composition of film(s) in contact with it. In the present embodiment, yttrium oxide film 5 is used as a contact film under hafnium oxide film 6. At this instance, hafnium oxide film 6 with silicon additives is capable of maintaining the orthorhombic phase ill structure even when yttrium is diffused into hafnium oxide film 6. Thus, it is possible to prevent the loss of ferroelectricity of hafnium oxide film 6 and thereby maintain the polarization properties required contributing to memory properties.

In the present embodiment, yttrium oxide film 5 is disposed in contact between oxide film 4 and hafnium oxide film 6 containing silicon additives. Thus, it is possible to increase the barrier height of hafnium oxide film 6 containing silicon additives and suppress leakage current. As a result, it is possible to reduce electricity consumption and provide a highly reliable flash memory device MD. It is further possible to configure hafnium oxide film 6 with silicon additives into a structure possessing ferroelectricity.

### Second Embodiment

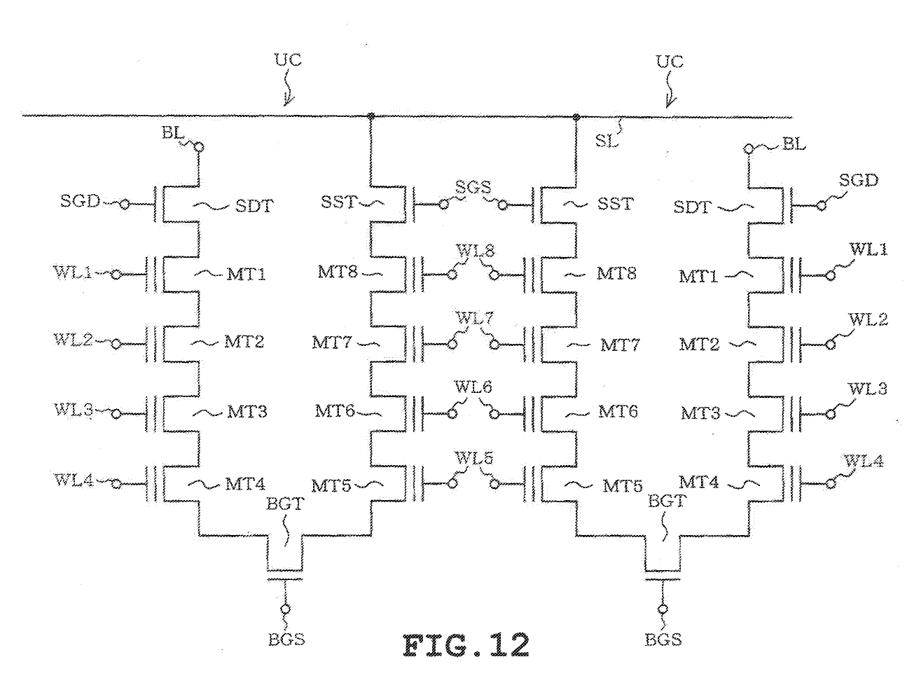

FIGS. 12 to 31 illustrate a second embodiment. The second embodiment is described based on a three-dimensional ferroelectric memory-cell unit structure.

FIG. 12 illustrates a circuit configuration of memory-cell unit UC provided in a memory-cell array of three-dimensional stacked ferroelectric memory cells. FIG. 12 provides an electrical representation of two memory-cell units UC provided in a semiconductor storage device. Electrical elements such as cell transistors MT1 to MT8, select transistors SDT and SST, word lines WL1 to WL8, and control lines of select gates SGD and SGS are illustrated symbolically.

As illustrated in FIG. 12, cell unit UC is provided with 2ⁿ (n≧2) number (8 for example) of cell transistors MT1 to MT8, drains-side select transistor SDT, source-side select transistor SST, and back-gate transistor BGT.

Starting from bit line BL and ending at source line SL, elements of cell unit UC are series connected electrically in the order of: drain-side select transistor SET, 2ⁿ⁻¹ number (4 for example) of cell transistors MT1 to MT4, back-gate transistor BGT, and 2ⁿ⁻¹ number (4 for example) of cell, transistors MT5 to MT8, and source-side select transistor SST.

Select gate SGD is connected to the gate of drain-side select transistor SDT. Select gate SGS is connected to the gate of source-side select transistor SST. Word lines WL1 to WL8 are connected to the gates of cell transistors MT1 to MT8, respectively. Back-gate line BGS is connected to the gate of back-gate transistor BGT.

Though not illustrated, a peripheral circuit is provided with various types of drive circuits (such as a hit-line drive circuit and a source-line drive circuit which are neither illustrated). These drive circuits are connected to select gates SGD and SGS, word lines WL1 to WL8, bit lines BL, and source lines SL and drive these electrical connection lines SGD, SGS, WL1 to WL8, BL, SL, and BGS.

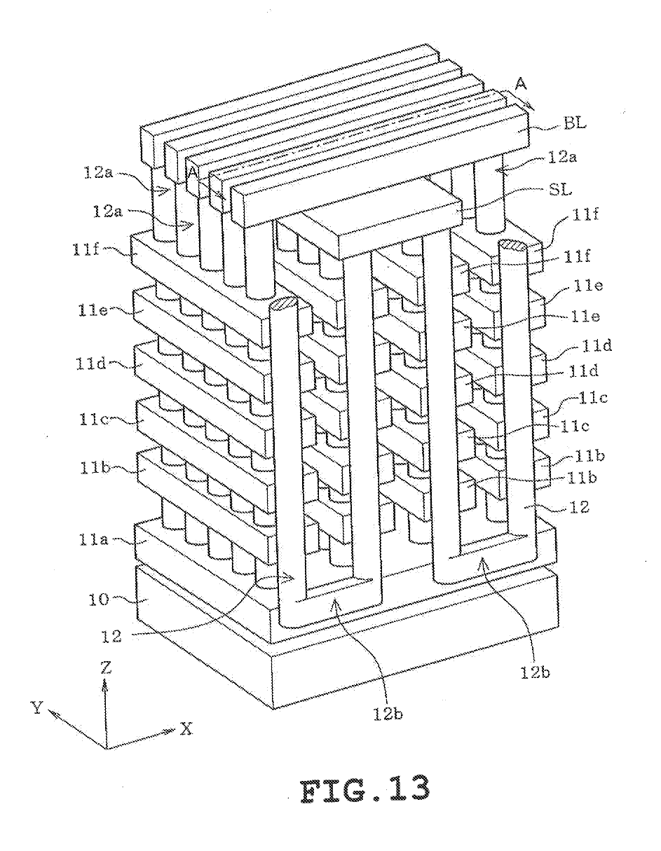

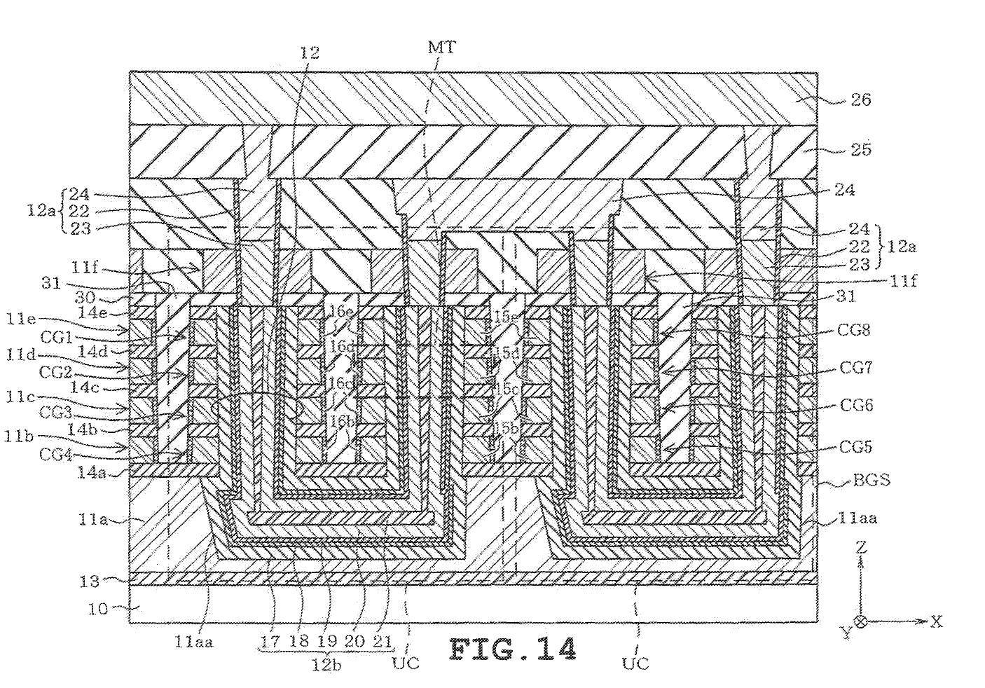

FIG. 13 one example of a perspective view schematically illustrating a memory-cell array of three-dimensional stacked ferroelectric memory-cell unit UC. FIG. 14 is one example of a cross-sectional view taken along line A-A of FIG. 13. The X direction is taken along the surface of semiconductor substrate 10. The Y direction crosses the X direction and is taken along the surface of semiconductor substrate 10. The Z direction is orthogonal to the surface of semiconductor substrate 10.

As illustrated in FIG. 13, back-gate conductive layer 11a (corresponding to back-gate line BGS), word line layers 11b to 11e (corresponding to word line layers WL4 to WL1), and select gate layer 11f (corresponding to select gates SGD or SGS) are formed one after another so as to be spaced from one another above (in the Z direction) a surface of semiconductor substrate 10.

In FIGS. 13 and 14 for example, layers 11 (back-gate conductive layer, word line layer, and select gate layer) formed in the same layer (in the same height in the S direction for example) are represented by appending identical suffixes a to e.

Back-gate conductive layer 11a is formed so as to be spaced in the Z-direction above the surface of semiconductor substrate 10 and lies along the XY plane (direction of the surface of semiconductor substrate 10). Back-gate conductive layer 11a comprises a conductive layer.

Further, there are multiple word line layers 11b to 11e as well as multiple select gate layers 11f, each extending in the Y direction and being isolated from one another in the X direction. Word line layers 11b to 11e and select gate layer 11f are aligned in the Z direction and each comprise a conductive layer.

At the X-direction center of each of word line layers 11b to 11e and select gate layer 11f aligned in the Z direction, a hole extending in the Z direction is formed. Sidewall layer 12 (in more detail, refer to the later described gate insulating layers 17 to 19, silicon film 20 (corresponding to a semiconductor channel region) serving as a channel film, and insulating film layer 21) extends along the inner walls of the holes so as to extend in the up and down direction (vertical direction: Z direction) through the holes.

Thus, each of word line layers 11b to 11e and select gate layer 11f are disposed so as to surround the entire X and Y direction surfaces of a portion of sidewall layer 12. The regions of word line layers 11b to 11e surrounding sidewall layer 12 serve primarily as cell gates CG. The regions of select gate layers 11f surrounding sidewall layer 12 serve primarily as select gate SGD or SGS.

Sidewall layer 12 formed along the sidewalls of the holes are formed into a columnar shape (a circular column or a rectangular column for example). FIG. 13 illustrates an example in which sidewall layer 12 is configured as a circular column, however, sidewall layer 12 may be configured, as a rectangular column. Sidewall layers 12 are disposed in a matrix when viewed in the Z direction. One sidewall layer 12 is provided for each stack of word line layers 11b to 11e and select gate layer 11f isolated in the X direction.

Further, link layer 12b is provided inside back-gate conductive layer 11a. Link layer 12b is a stacked structure similar to sidewall layer 12 and is configured so as to be linked with link layer 12b. Two sidewall layers 12 aligned in the X direction are linked inside back-gate conductive layer 11a by link layer 12b. As a result, two sidewall layers 12 adjacent in the X direction and being linked by link layer 12b form a pair.

Thus, as illustrated in FIG. 13, sidewall lavers 12 being linked by link layer 12b exhibit a so-called U shape as viewed in the XZ cross section. Bit line BL is formed at one and (above the Z-direction upper surface) of side layers 12 linked in a U shape, whereas source line SL is formed at the other end (above the Z-direction upper surface) of side layers 12 linked in a U shape.

As illustrated in FIG. 12, select transistor SDT, cell transistors MT1 to MT4, back-gate transistor BGT, cell transistors MT5 to MT8 and select transistor SDT form a single cell unit UC. As illustrated in FIG. 13, sidewall layers 12 are formed so as to link the semiconductor channel regions of each of the transistors SDT, MT1 to MT4, BGT, MT5 to MT8, and SDT belonging to a single cell unit UC.

Referring FIG. 14, the structures briefly illustrated in FIG. 13 will be described in detail. Above semiconductor substrate 10, back-gate conductive layer 11a, serving as back-gate line BGS, is disposed via back-gate insulating layer 13. Back-gate conductive layer 11a comprises, for example, a conductive layer such as a polysilicon doped with impurities.

Above back-gate layer 11a, inter-word-line insulating layers 14a to 14e and word line layers 11b to 11e are stacked alternately. In other words, layers are stacked above the upper surface of back-gate conductive layer 11a in the order of: 14a→11b→14b→11c→14c→11d→14d→11e→14e. Each of inter-word-line insulating layers 14a to 14e comprises, for example, a silicon oxide film. Holes extending in the Z direction are formed through inter-word-line insulating layers 14a to 14e and word line layers 11b to 11e. Sidewall layer 12 is formed along the inner walls of these holes.

The regions of word line lavers 11b to 11e contacting the outer periphery of sidewall layers 12 serve as cell gates (control electrodes) CG1 to CG4, respectively. Cell gates CG1 to CG4 are provided with conductive films 15b to 15e and conductive films 16b to 16e, respectively. Conductive films 15h to 15e are formed so as to cover the XY planes of sidewall layer 12. Conductive films 16b to 16e are formed along the side surfaces of conducive films 15b to 15e, respectively. Conductive films 15b to 15e comprise, for example, a polysilicon doped with impurities. Conductive films 16b, to 16e comprise, for example, a silicide.

Trench 11aa is formed into back-gate conductive layer 11a. Trench 11aa is filled with link layer 12b which extends in a columnar shape along the X direction. FIG. 14 illustrates the bottom portion of trench 11aa being higher than the upper surface of insulating film 13. However, the bottom portion of trench 11aa may reach the upper surface of insulating film 13.

Sidewall layer 12 extends continuously in the Z direction along the inner-side walls of cell gates CG1 to CG4 and the inner-side wails of inter-word-line insulating lavers 14a to 14e from the end of link layer 12b extending in the X direction within trench 11aa. Both sidewall layer 12 and link layer 12b are provided with hafnium oxide film 17, yttrium oxide film 18, silicon oxide film 19, silicon film 20, and insulating film layer 21, one after another from the outer peripheral side to the inner peripheral side thereof.

Hafnium oxide film 17 contains Yttrium (Y) additives. Hafnium oxide film 17 is formed, for example, like a ring-shaped column (a circular ring-shaped column or a rectangular ring-shaped column for example). The thickness of hafnium oxide film 17 taken in the direction in which the film is grown ranges approximately from 5 nm to 20 nm. In one example, hafnium oxide film 17 is approximately 10 nm thick (thickness of a ring-shaped column). The yttrium concentration in hafnium oxide film 17 is preferably controlled so that atomicity ratio of yttrium (Y) and hafnium (Hf) satisfies 0.001≦Y/(Hf+Y)≦0.06.

Further, the structure of hafnium oxide film 17 is preferably orthorhombic phase III. Hafnium oxide film 17 is preferably ferroelectric. The atomicity of yttrium (Y) can be measured by XPS, atom probe, or the like. It has been found that hafnium oxide film 17 exhibits ferroelectricity when the crystal structure is orthorhombic phase III.

Further, yttrium oxide film 18 is formed for example like a ring-shaped column (such as a circular ring-shaped column or a rectangular ring-shaped column) so as to be disposed along the inner-side wall of hafnium oxide film 17 in contact with hafnium oxide film 17. The thickness of yttrium oxide film 18 taken in the direction in which the film is grown (thickness of a ring-shaped column) is less (ranges approximately from 0.1 nm to 0.5 nm. In one example, yttrium oxide film 18 is approximately 0.3 nm thick) than the thickness of hafnium oxide film 17 described earlier.

Further, silicon oxide film 19 is formed for example like a ring-shaped column (such as a circular ring-shaped column or a rectangular ring-shaped column) so as to be disposed along the inner-side wall of yttrium oxide film 18 in contact with yttrium oxide film 18. The thickness of silicon oxide film 19 taken in the direction in which the film is grown ranges approximately from 0.3 nm to 2.0 nm. In one example, silicon oxide film 19 is approximately 0.5 nm thick (thickness of a ring-shaped column).

Further, silicon film 20 is formed for example like a ring-shaped column (such as a circular ring-shaped column or a rectangular ring-shaped column) so as to be disposed along the inner-side wall of silicon oxide film 19 in contact with silicon oxide film 19. Silicon film 20 is formed in a continuous manner and serves as a semiconductor channel region for each of the elements illustrated in FIG. 12, namely, SDT, MT1 to MT4, BGT, MT5 to MT8, and SST. In the central side of the inner-side wall of silicon film 20, insulating film layer 21 serving as a core portion of the columnar structure is formed.

Memory cell MT is formed in a region where sidewall layer 12 and word line layer 11 cross over. Memory cell MT is provided with silicon oxide film 19, yttrium oxide film 18, hafnium oxide film 17, conductive film 15, and conductive film 16 which are disposed along the outer side surface of silicon oxide film 19. The above described three-dimensional stack structure is also capable of storing information in memory-cell MT by utilizing the polarizing properties of sidewall layer 12 as was the case in the previous embodiment.

Further, sidewall layer 12 is formed continuously across memory cells MT adjacent in the Z direction. Thus, electric field leakage may cause polarization of gate insulating layer 2 disposed between the adjacent memory cells MT and possibly cause memory malfunctioning. However, the atomicity ratio of hafnium oxide film 17 is controlled to satisfy 0.001>Y/(Hf+Y) or Y/(Hf+Y)>0.06. Thus, sidewall layer 12 may be configured so as not to exhibit ferroelectricity. Thus, it is possible to prevent memory malfunctioning between the adjacent memory cells MT caused by electric field leakage.

Insulating layer 30 is formed above the upper surface of inter-word-line insulating layer 14e. Insulating layer 30 comprises for example a silicon oxide film. Insulating layer 31 is formed between word-lines layers 11b to 11e adjacent in the X direction and between inter-word-line insulating layers 14b to 14e adjacent in the X direction. Insulating layer 31 comprises for example a silicon oxide film. The upper surfaces of insulating layers 30 and 31 are coplanar. Select gate layer 11f serving as select gate SGD is stacked above insulating layer 30.

Sidewall layer 12 described earlier is provided with upper portion 12a extending along the sidewalls of insulating layer 30. Upper portion 12a includes gate insulating film 22 and conductive layers 23 and 24 serving as a semiconductor channel region.

Gate insulating film 22 is formed, for example, like a ring-shaped column (such as a circular ring-shaped column or a rectangular ring-shaped column) and conductive layer 23 is filled along the inner side of gate insulating film 22. Gate insulating film 22 comprises, for example, a silicon oxide film. Conductive layer 23 comprises, for example, a polysilicon doped with impurities. Select gate layer 11f may comprise, for example, a polysilicon. Select gate layer 11f is configured to cover the entire XY direction perimeter of conductive layer 23 and gate insulating film 22 of upper portion 12a of sidewall layer 12.

Conductive layer 24 is filled above the upper surface of conductive layer 23. Conductive layer 24 comprises, for example, a polysilicon doped with impurities. Interlayer insulating film 25 is formed above conductive layer 24 and conductive layer 26 is formed above interlayer insulating film 25. Interlayer insulating film 25 comprises, for example, a silicon oxide film. Conductive layer 26 comprises, for example, a polysilicon doped with impurities.

As illustrated in FIG. 14, source line SL is structurally connected to conductive layers 23 and 24 in the region between cell units UC adjacent in the X direction, and bit line BL is structurally connected to conductive layers 23, 24, and 26.

Sidewall layers 12, being linked in the shape of a letter “U” in the XZ plane, may alternatively be shaped like a letter “I”. In one example of a letter “I” structure, trench 11aa and link layer 12b is absent and source line SL is disposed in semiconductor substrate 10. Thus, sidewall layer 12 is connected to source line SL in semiconductor substrate 10 without being bent in the X direction.

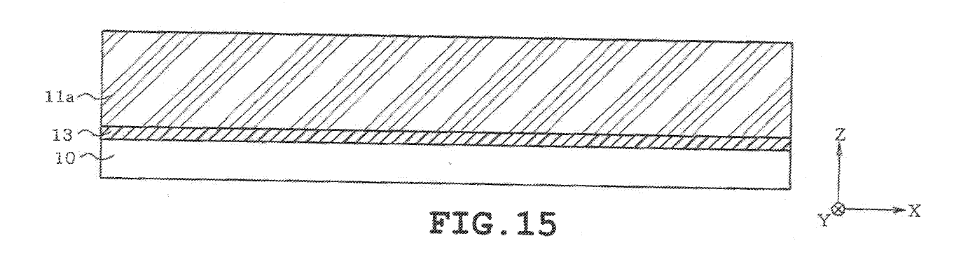

A manufacturing process flow of the above described structure will be given hereinunder. Referring to FIG. 15, oxidized silicon for example, serving as back-gate insulating layer 13, is formed above semiconductor substrate 10. Above back-gate insulating layer 13, a polysilicon is formed which serves as back-gate conductive layer 11a.

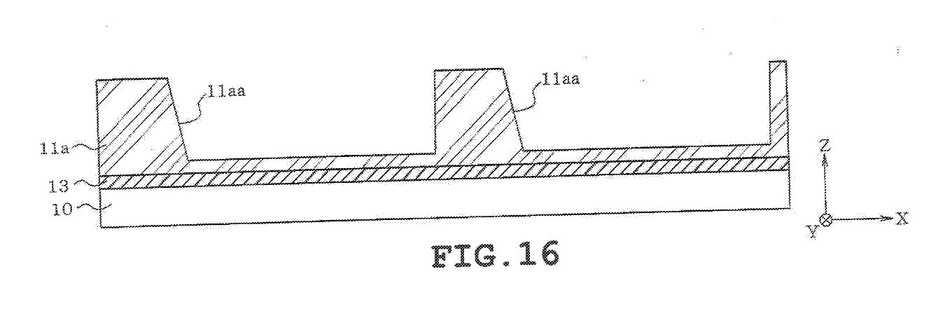

As illustrated in FIG. 16, back-gate conductive layer 11a is anisotropically etched by lithography and RIE to form trenches 11aa. Trenches 11aa are formed so as to appear as rectangular openings in plan view.

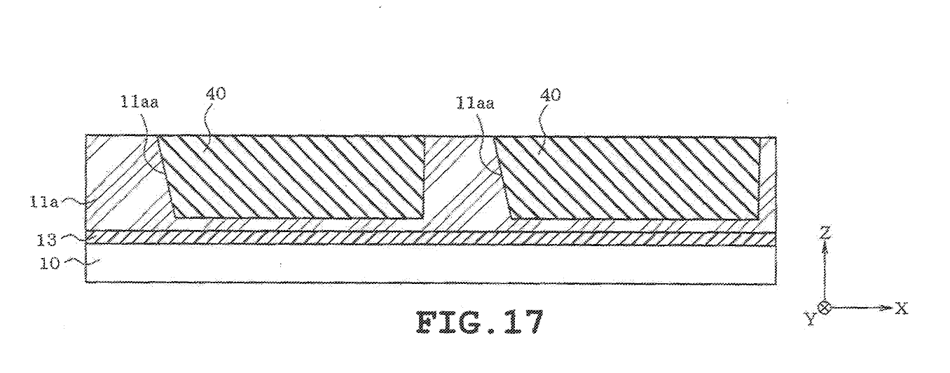

As illustrated in FIG. 17, silicon nitride (SiN), serving as first sacrificial layer 40, is deposited so as to fill trenches 11aa. First sacrificial layer 40 is planarized by CMP or etched back by RIE so as to remain in trenches 11aa.

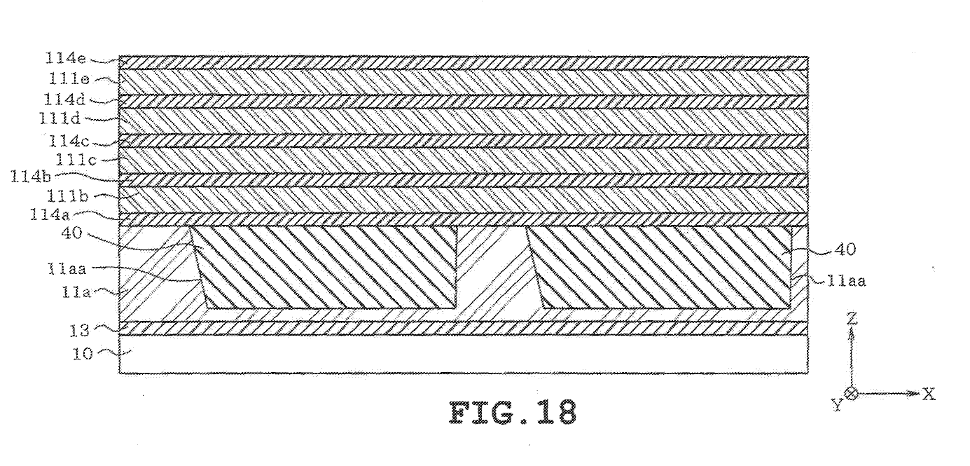

As illustrated in FIG. 18, insulating films 114a to 114d comprising oxidized silicon (SiO₂) for example and conductive films 111b to 111e comprising polysilicon for example are deposited alternately by CVD above back-gate insulating layer 13, back-gate conductive layer 11a, and first sacrificial layer 40. Further, insulating film 114e comprising an oxidized silicon is further formed above the upper surface of the topmost conductive film 111e.

The deposited insulating films 114a to 114e serve as inter-word-line insulating layers 14a to 14e. The deposited conductive films 111b to 111e serve as word line layers 11b to 11e. Conductive films 111b to 111e and insulating films 114a to 114e are formed along the XY plane (2-dimensional plane) orthogonal to the direction in which they are stacked (Z direction of FIG. 17).

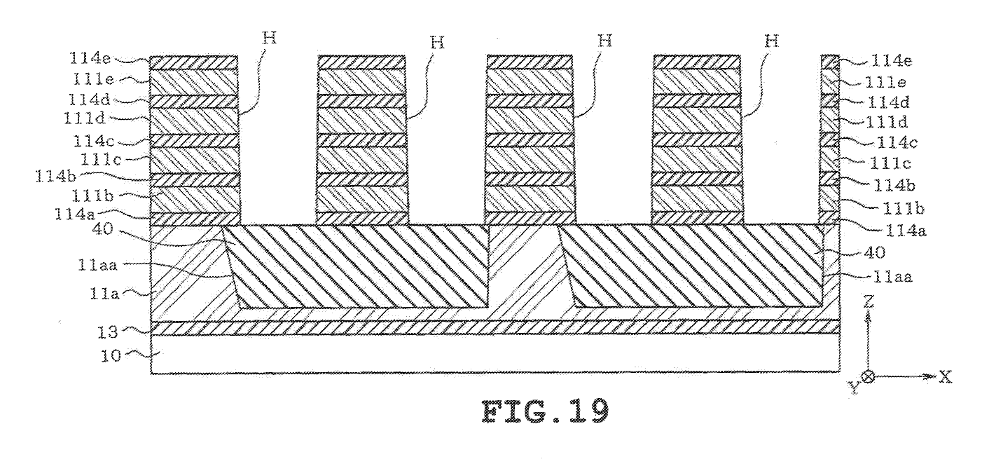

As illustrated in FIG. 19, holes H penetrating through conductive films 111b to 111e and insulating films 114a to 114e are formed by anisotropic etching. As illustrated in FIG. 19 depicted so as to correspond to FIG. 14, two holes H are formed per cell unit UC. These holes H are formed so as to reach the vicinity of the two edges of the upper surfaces of the filled first sacrificial layers 40.

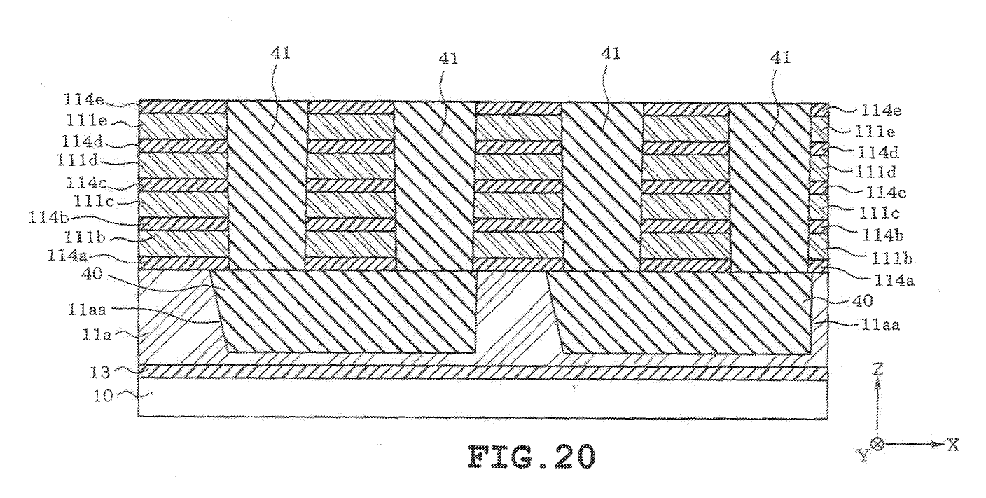

As illustrated in FIG. 20, holes H are filled with silicon nitride (SiN) serving as second sacrificial layers 41. The upper surfaces of second sacrificial layers 41 are processed by CMP, RIE, or the like, so as to be substantially level with the upper surface of the topmost insulating film 114e.

The above described process steps for stacking insulating films 114a to 114e and conductive films 111b to 111e, forming holes H, and filling second sacrificial layers 41, may be further repeated thereafter in order to form further multiple layers of conductive films 111b to 111e (word line levers 11b to 11e). Such process steps will not be described in the present embodiment for convenience of explanation.

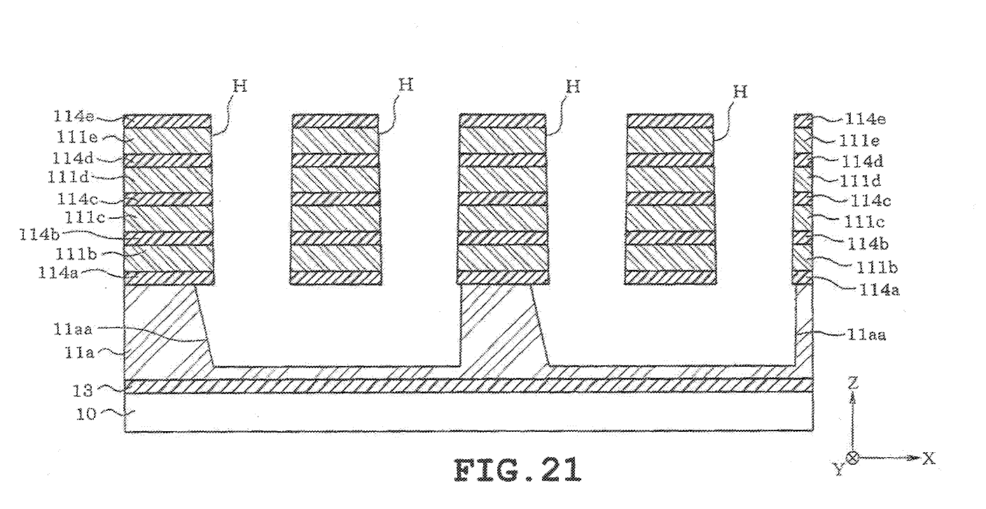

As illustrated in FIG. 21, first and second sacrificial layers 40 and 41 are removed. The removal of first and second sacrificial layers 40 and 41 may be performed for example in a solution of hot phosphoric acid. Penetrating through holes H and trenches 11aa are formed by way of the foregoing process steps.

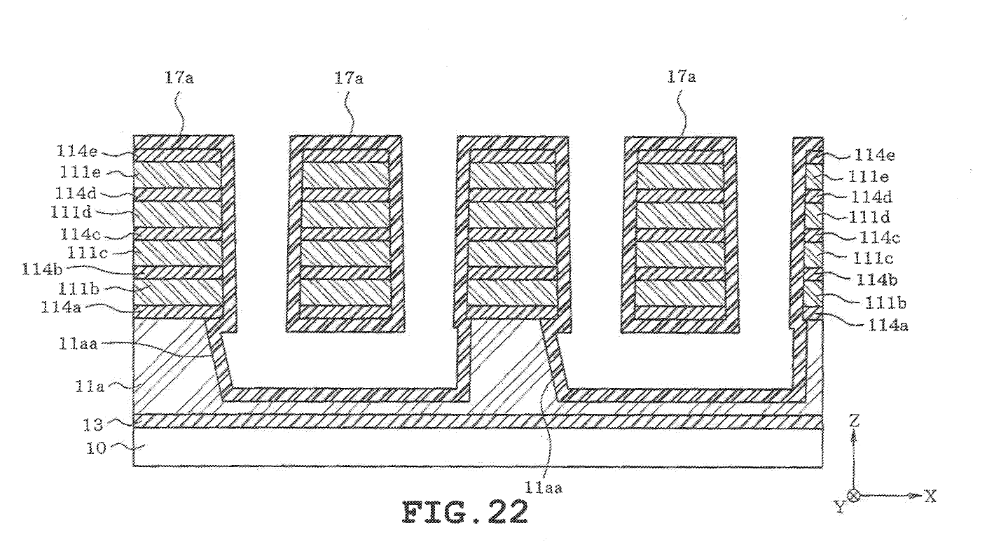

As illustrated in FIG. 22, amorphous film 17a containing yttrium additives is formed along the exposed surfaces of holes H and trenches 11aa by ALD. Hafnium oxide film 17a is formed so as to be approximately 5 nm to 20 nm thick. In one example, hafnium oxide film 17a is formed so as to be 10 nm thick. As a result, hafnium oxide film 17a is formed primarily along the sidewalls of insulating films 114a to 114e and conductive films 111b to 111e.

Hafnium oxide film 17a is also formed along other exposed surfaces (such as the exposed upper surface of insulating film 14e of the topmost layer, the exposed under surface of insulating film 14a of the lowermost layer, and the inner surface of trench 11aa). The yttrium concentration in hafnium oxide film 17a containing yttrium additives is preferably controlled so that atomicity ratio of yttrium and hafnium satisfies 0.001≦Y/(Hf+Y)≦0.06.

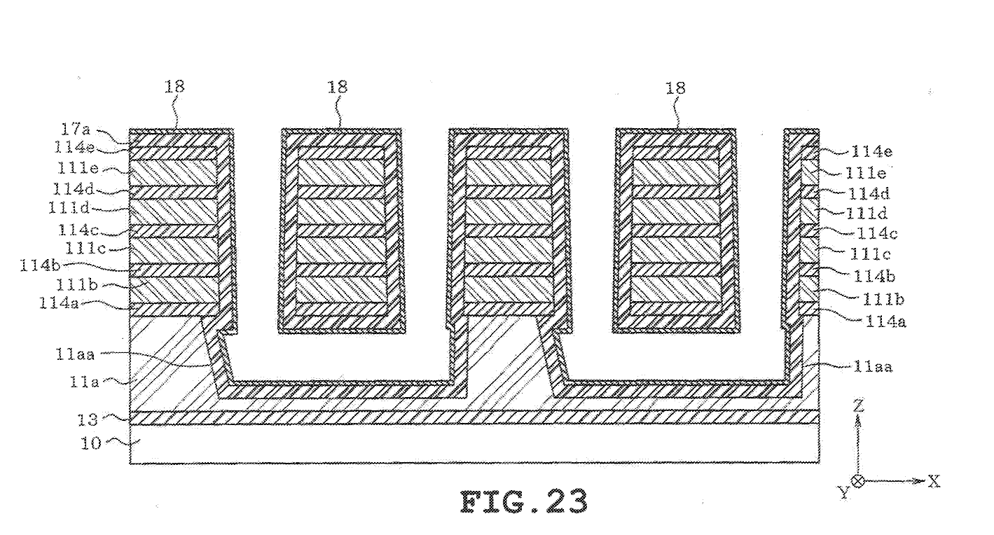

As illustrated in FIG. 23, yttrium oxide film 18 is formed by ALD so as to contact the exposed surface of amorphous hafnium oxide film 17a containing yttrium additives. Yttrium oxide film 18 is formed so as to be approximately 0.1 nm to 0.5 nm thick. In one example, yttrium oxide film 18 is formed so as to be 0.3 nm thick. Yttrium oxide film 18 is formed so as to cover hafnium oxide film 17a.

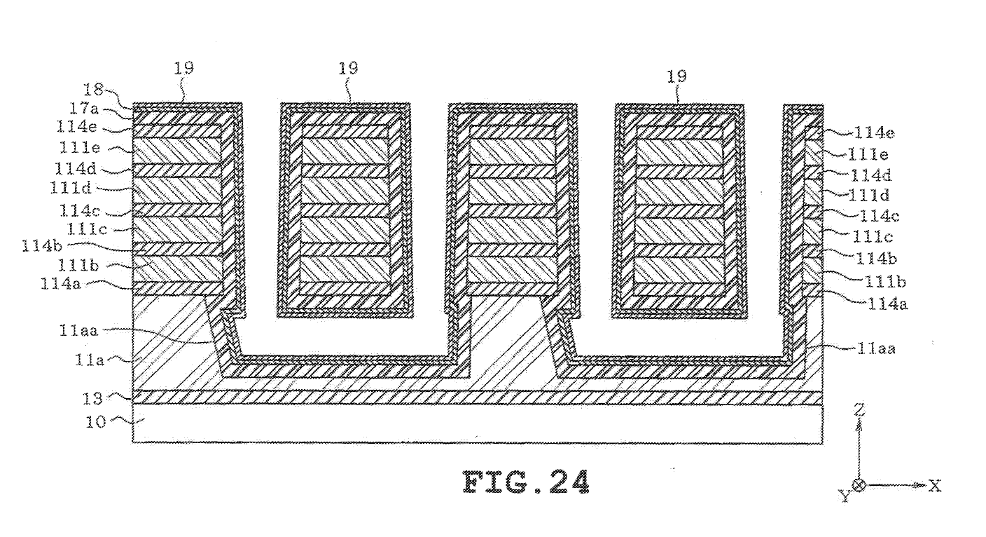

As illustrated in FIG. 24, silicon oxide film 19 is formed by ALD so as to contact the exposed surface of yttrium oxide film 18. Silicon oxide film 19 is formed so as to be approximately 0.3 nm to 2.0 nm thick. In one example, silicon oxide film 19 is formed so as to be 0.5 nm thick.

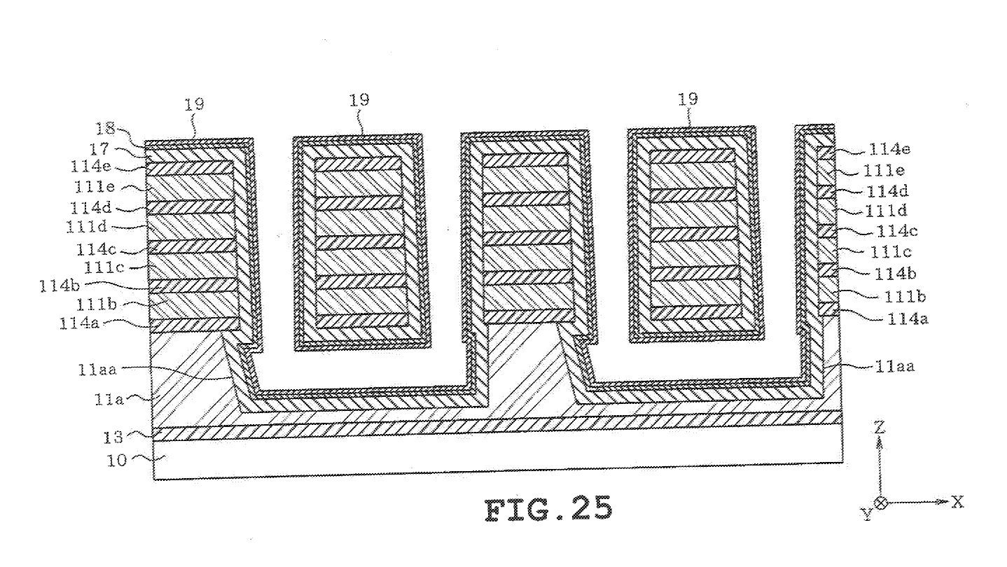

As illustrated in FIG. 25, RTA (Rapid Thermal Anneal) is performed at temperatures ranging approximately from 800 degrees Celsius to 1100 degrees Celsius to obtain hafnium oxide film 17 containing yttrium additives being crystallized into orthorhombic phase III. In one example, RTA is performed at 1000 degrees Celsius. The timing of crystallization anneal is not limited to this timing. Crystallization to orthorhombic phase III gives ferroelectricity to hafnium oxide film 17.

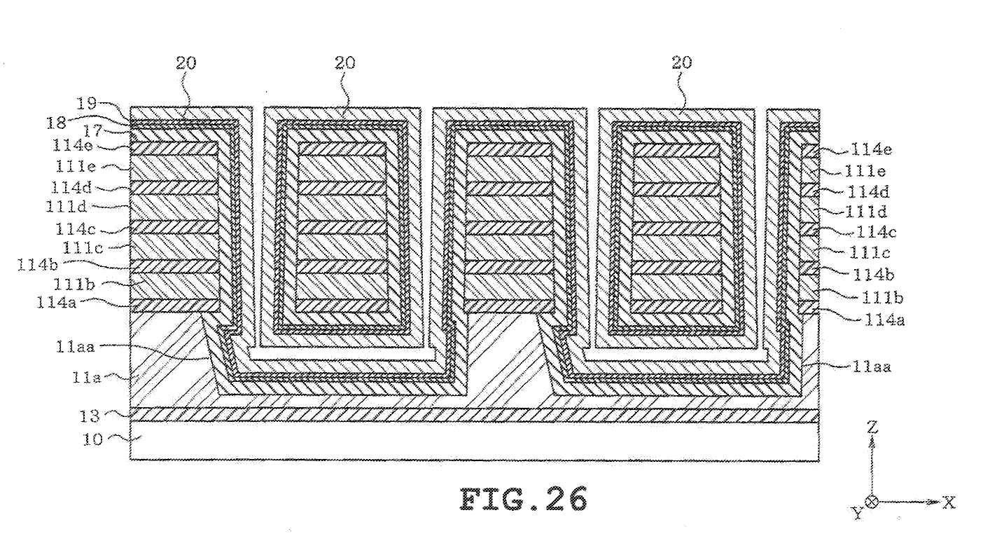

As illustrated in FIG. 26, silicon film 20 serving as a semiconductor channel region is deposited along the inner side of silicon oxide film 19. Silicon film 20 is deposited in the amorphous state.

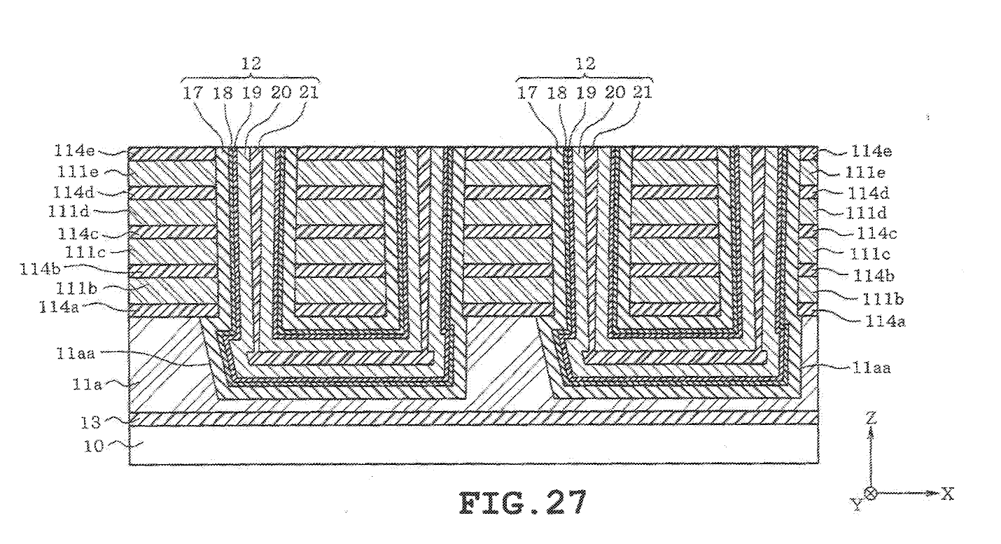

As illustrated in FIG. 27, the surface of the inner-side wall of silicon film 20 is thermally oxidized to obtain an oxidized silicon (SiO₂). As a result, insulating film layer 21 is formed along the exposed surface of silicon film 20. At this instance, the remaining silicon film 20 is polycrystallized into polysilicon. Further, the holes are filled by depositing oxidized silicon film by CVD. As a result, insulating film layer 21 is configured as the core portion. Further, as illustrated in FIG. 27, the structure is planarized by CMP to the upper surface of the topmost insulating film 114e. As a result, stacked structures 17 to 21 are removed except for the portions located in each of holes H.

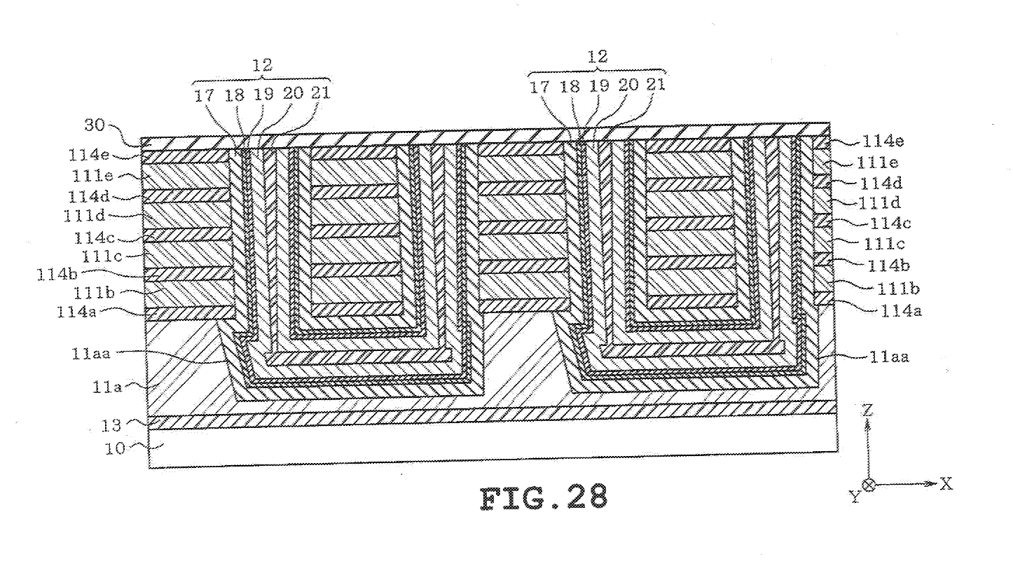

As illustrated in FIG. 28, silicon nitride (SiN) for example is deposited by CVD to form insulating layer 30 serving as a protection film.

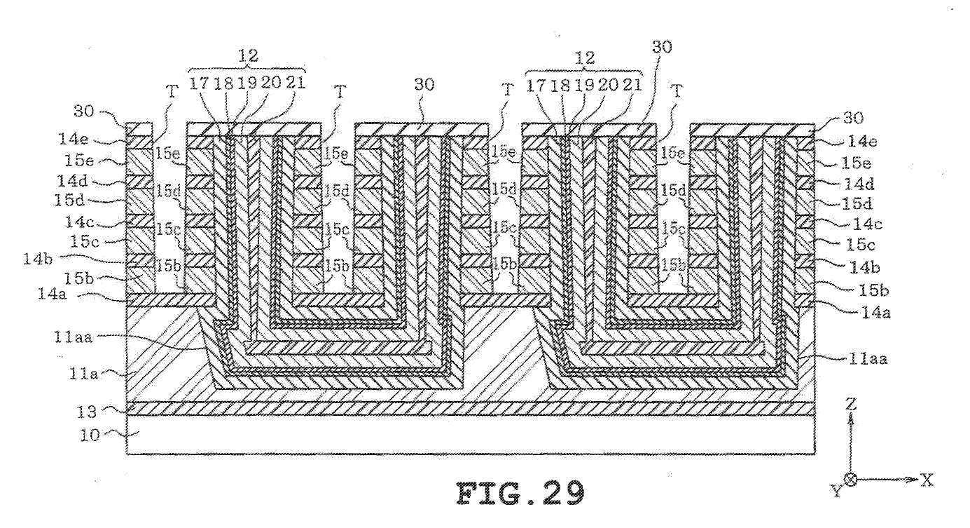

As illustrated in FIG. 29, memory isolation trenches T are formed which extends in a line (along the direction normal to the page of the figure). Memory isolation trenches T are formed in each of two adjacent holes H using the lowermost insulating film 114a (represented as inter-word-line insulating layer 14a in FIG. 29) a stopper. As a result, conductive films 111b to 111e are isolated in the X direction by memory isolation trenches T and are each ultimately formed into conductive films 15b to 15e serving as cell gates CG1 to CG8. Conductive films 15b to 15e comprise, for example, a polysilicon doped with impurities.

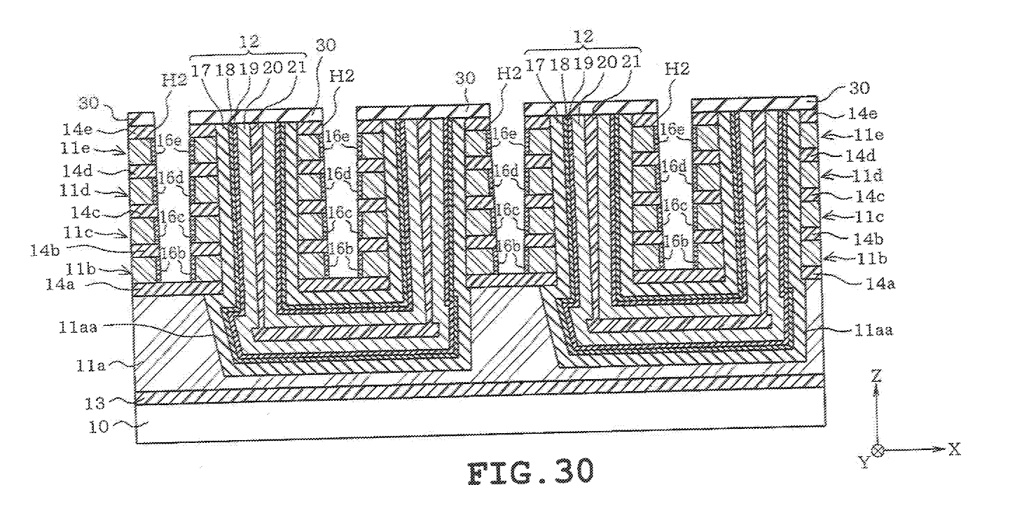

As illustrated in FIG. 30, cobalt (Co) is deposited by CVD along the sidewalls of memory isolation trenches T. Further, RTA is performed to cause reaction of cobalt in the exposed surfaces of conductive films 15b to 15e and trenches T to form silicides serving as conductive films 16b to 16e. Conductive films 16b to 16e are formed along the sidewalls of conductive films 15b to 15e. The unreacted cobalt is removed by a mixed solution of sulfuric acid and hydrogen peroxide water.

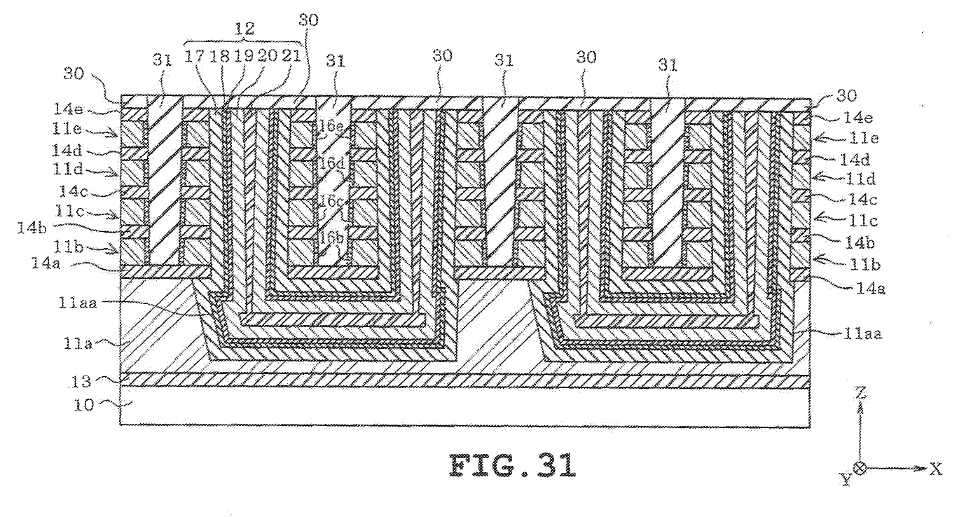

As illustrated in FIG. 31, insulating layer 31 is deposited in memory isolation trenches T. Then, though not described, structures of select gates SGD and SGS (select gate layer 11f), source line SL (conductive film 24), interlayer insulating film 25, and bit line BL (conductive film 26) are formed as illustrated in FIG. 14.

The present embodiment describes a three-dimensional stacked-structure application in which yttrium (Y) is added to hafnium oxide film 17 instead of silicon (Si) added in the previous embodiment. Yttrium oxide film 18 is formed between hafnium oxide film 17 containing yttrium and oxide film 19 so as to contact hafnium oxide film 17 containing yttrium and oxide film 19.

It is possible to form an interface dipole by yttrium oxide film 18 disposed between oxide film 19 and hafnium oxide film 17 in the above described structure as well. As a result, barrier height of hafnium oxide film 17 with respect to electrons is increased and thereby suppresses leakage current. Thus, it is possible to reduce electricity consumption and provide a highly reliable semiconductor storage device.

Hafnium oxide film 17 containing yttrium additives is preferably controlled so that atomicity ratio of yttrium (Y) and hafnium (Hf) satisfies 0.001≦Y(Hf+Y)≦0.06.

### Third Embodiment

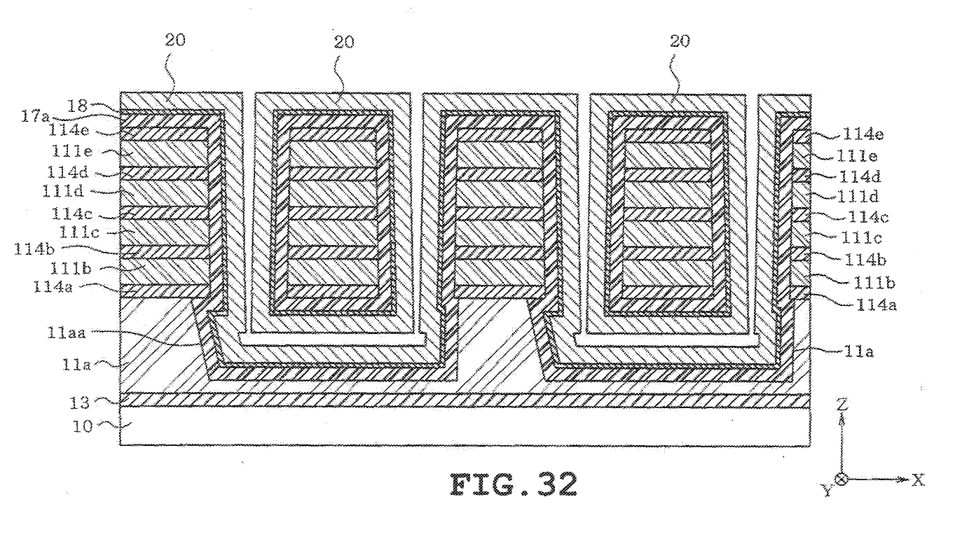

FIG. 32 illustrates a third embodiment. After forming yttrium oxide film 18 as illustrated in FIG. 23, silicon film 20 serving as a semiconductor channel region is deposited as illustrated in FIG. 32 without forming silicon oxide film 19. Then, silicon film 20 is thermally oxidized to form silicon oxide film between yttrium oxide film 18 and silicon film 20 as illustrated in FIG. 26. It is possible to obtain structures similar to those of the previous embodiment by employing such manufacturing process flow as well.

### Modified Embodiments

Modified embodiments are described below. In the previous embodiments, silicon (Si) or yttrium (Y) was added to hafnium oxide film 6, 17. Aluminum (Al) or zirconium (Zr) may be added instead of yttrium (Y).

When adding aluminum (Al) to hafnium oxide film 6, 17, atomicity ratio of hafnium and aluminum preferably satisfies 0.04≦Al/(Hf+Al)≦0.1.

When adding zirconium (Zr) to hafnium oxide film 6, 17, atomicity ratio of hafnium and zirconium preferably satisfies 0.3≦Zr/(Hf+Zr)≦0.7.

In the first embodiment, silicon (Si) was used for example as the material for semiconductor substrate 1. However, a germanium (Ge) substrate or a silicon germanium (SiGe) substrate may be used for example as semiconductor substrate 1.

When using a germanium (Ge) substrate, oxide film 4 serving as gate insulating layer 2 preferably comprises a germanium oxide film. When using a silicon germanium (SiGe) substrate, oxide film 4 serving as gate insulating layer 2 preferably comprises a silicon germanium (SiGe) oxide film.

Further, silicon film 20, serving as a semiconductor channel region in the second embodiment, may be replaced by a film containing germanium (Ge) as a primary component or a film containing silicon (Si) and germanium (Ge) as primary components. That is, the region serving as the semiconductor channel region is preferably formed of a film containing silicon (Si) and/or germanium. (Ge) as primary component(s).

Further, oxide film 4 may be replaced by a silicon oxynitride film containing nitride additives. When a germanium substrate is used as semiconductor substrate 1, oxide film 4 may be replaced by a germanium oxynitride film. When a silicon germanium substrate is used as semiconductor substrate 1, oxide film 4 may be replaced by a silicon germanium oxynitride film.

### Further Modifications

The claims describe examples of concepts derivable from high-level, mid-level, or low-level abstractions of the configurations of the foregoing embodiments or modified embodiments; or from combinations of some or all of the configurations of the foregoing embodiments or modified embodiments. Alternatively, the concepts may be described as follows.

### [Aspect 1]

One aspect including, forming an oxide film above an upper surface of a semiconductor channel region,

forming an yttrium oxide film above an upper surface of the oxide film,

forming an amorphous hafnium oxide film containing silicon additives above an upper surface of the yttrium oxide film,

forming a control electrode above an upper surface of the hafnium oxide film containing silicon additives, and

crystallizing the amorphous hafnium oxide film containing silicon additives into an orthorhombic phase III.

### [Aspect 2]

One aspect including, forming, an oxide film above an upper surface of a semiconductor channel region,

forming an yttrium oxide film above an upper surface of the oxide film,

forming an amorphous hafnium oxide film containing yttrium additives above an upper surface of the yttrium oxide film,

forming a control electrode above an upper surface of the hafnium oxide film containing yttrium additives, and

crystallizing the amorphous hafnium oxide film containing yttrium additives into an orthorhombic phase III.

### [Aspect 3]

One aspect including, forming an oxide film above an upper surface of a semiconductor channel region,

forming an yttrium oxide film above an upper surface of the oxide film,

forming an amorphous hafnium oxide film containing aluminum additives above an upper surface of the yttrium oxide film,

forming a control electrode above an upper surface of the hafnium oxide film containing aluminum additives, and

crystallizing the amorphous hafnium oxide film containing aluminum additives into an orthorhombic phase III.

### [Aspect 4]

One aspect including, forming an oxide film above an upper surface of a semiconductor channel region,

forming an yttrium oxide film above an upper surface of the oxide film,

forming an amorphous hafnium oxide film containing zirconium additives above an upper surface of the yttrium oxide film,

forming a control electrode above an upper surface of the hafnium oxide film containing zirconium additives, and

crystallizing the amorphous hafnium oxide film containing zirconium additives into an orthorhombic phase III.

### [Aspect 5]

One aspect including, forming conductive layers of cell gates above a semiconductor substrate, the conductive layers being insulated from one another by insulating films,

forming a hole extending through the conductive layers of the cell gates,

forming an amorphous hafnium oxide film containing silicon additives along an inner-side wall of the hole,

forming an yttrium oxide film along an inner-side wall of the hafnium oxide film containing silicon additives,

forming an oxide film along an inner-side wall of the yttrium oxide film,

forming a semiconductor channel region along an inner-side wall of the oxide film, and

crystallizing the amorphous hafnium oxide film containing silicon additives.

### [Aspect 6]

One aspect including, forming conductive layers of cell gates above a semiconductor substrate, the conductive layers being insulated from one another by insulating films,

forming a hole extending through the conductive layers of the cell gates,

forming an amorphous hafnium oxide film containing silicon additives along an inner-side well of the hole,

forming an yttrium oxide film along an inner-side wall of the hafnium oxide film containing silicon additives,

forming a semiconductor channel region along an inner-side wall of the yttrium oxide film,

crystallizing the amorphous hafnium oxide film containing silicon additives and forming an oxide film of the semiconductor channel, region between the yttrium oxide film and the semiconductor channel region.

### [Aspect 7]

One aspect including, forming conductive layers of cell gates above a semiconductor substrate, the conductive layers being insulated from one another by insulating films,

forming a hole extending through the conductive layers of the cell gates,

forming an amorphous hafnium oxide film containing yttrium additives along en inner-side wall of the hole,

forming an yttrium oxide film, along an inner-side wall of the hafnium oxide film containing yttrium additives,

forming an oxide film along an inner-side wall of the yttrium oxide film,

forming a semiconductor channel region along an inner-side wall of the oxide film, and

crystallizing the amorphous hafnium oxide film containing yttrium additives.

### [Aspect 8]

One aspect including, forming conductive layers of cell gates above a semiconductor substrate, the conductive layers being insulated from one another by insulating films,

forming a hole extending through the conductive layers of the cell gates,

forming an amorphous hafnium oxide film containing yttrium additives along an inner-side wall of the hole,

forming an yttrium oxide film along an inner-side wall of the hafnium oxide film containing yttrium additives,

forming a semiconductor channel region along an inner-side wall of the yttrium oxide film,

crystallizing the amorphous hafnium oxide film containing yttrium additives and forming an oxide film of the semiconductor channel region between the yttrium oxide film and the semiconductor channel region.

### [Aspect 9]

One aspect including, forming conductive layers of cell gates above a semiconductor substrate, the conductive layers being insulated from one another by insulating films,

forming a hole extending through the conductive layers of the cell gates,

forming an amorphous hafnium oxide film containing aluminum additives along an inner-side wall of the hole,

forming an yttrium oxide film along an inner-side well of the hafnium oxide film containing aluminum additives,

forming an oxide film along an inner-side wall of the yttrium oxide film,

forming a semiconductor channel region along an inner-side wall of the oxide film, and

crystallizing the amorphous hafnium oxide film containing aluminum additives.

### [Aspect 10]

One aspect including, forming conductive layers of cell gates above a semiconductor substrate, the conductive layers being insulated from one another by insulating films,

forming a hole extending through the conductive layers of the cell gates,

forming an amorphous hafnium oxide film containing aluminum additives along an inner-side wall of the hole,

forming an yttrium oxide film along an inner-side wall of the hafnium oxide film containing aluminum additives,

forming a semiconductor channel region along en inner-side wall of the yttrium oxide film,

crystallizing the amorphous hafnium oxide film containing aluminum additives and forming an oxide film of the semiconductor channel region between the yttrium oxide film and the semiconductor channel region.

### [Aspect 11]

One aspect including, forming conductive layers of cell gates above a semiconductor substrate, the conductive layers being insulated from one another by insulating films,

forming a hole extending through the conductive layers of the cell gates,

forming an amorphous hafnium oxide film containing zirconium additives along an inner-side wall of the hole,

forming an yttrium oxide film along an inner-side wall of the hafnium oxide film containing zirconium additives,

forming an oxide film along an inner-side wall of the yttrium oxide film,

forming a semiconductor channel region along an inner-side wall of the oxide film, and

crystallizing the amorphous hafnium oxide film containing zirconium additives.

### [Aspect 12]

One aspect including, forming conductive layers of cell gates above a semiconductor substrate, the conductive layers being insulated from one another by insulating films,

forming a hole extending through the conductive layers of the cell gates,

forming an amorphous hafnium oxide film containing zirconium additives along an inner-side wall of the hole,

forming an yttrium oxide film along an inner-side wall, of the hafnium oxide film containing zirconium additives,

forming a semiconductor channel region along an inner-side wall of the yttrium oxide film,

crystallizing the amorphous hafnium oxide film containing zirconium additives and forming an oxide film of the semiconductor channel region between the yttrium oxide film and the semiconductor channel region.

### [Aspect 13]

In one aspect, the oxide film primarily comprises a silicon oxide and/or a germanium oxide.

### [Aspect 14]

In one aspect, the control electrode includes a metal nitride layer.

### [Aspect 15]

In one aspect, the hafnium oxide film containing silicon additives includes silicon (Si) elements such that an atomicity ratio satisfies 0.02≦Si/(Hf+Si)≦0.05.

### [Aspect 16]

In one aspect, the hafnium oxide film containing yttrium additives includes yttrium (Y) elements such that an atomicity ratio satisfies 0.001≦Y/(Hf+Y)≦0.06.

### [Aspect 17]

In one aspect, the hafnium oxide film containing aluminum additives includes aluminum (Al) elements such that an atomicity ratio satisfies 0.04≦Al/(Hf+Al)≦0.01.

### [Aspect 18]

In one aspect, the hafnium oxide film containing zirconium additives zirconium (Zr) elements such that an atomic ratio satisfies 0.3≦Zr/(Hf+Zr)≦0.7.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor storage device comprising:
a semiconductor channel region;
a first insulating layer including an oxide film disposed in contact with the semiconductor channel region, an yttrium oxide containing film disposed on the oxide film, and a hafnium oxide film having an orthorhombic phase III structure disposed on the yttrium oxide containing film; and
a control electrode disposed on the first insulating layer.

2. The semiconductor storage device according to claim 1, wherein the semiconductor channel region comprises silicon (Si).

3. The semiconductor storage device according to claim 1, wherein the semiconductor channel region comprises germanium (Ge) or silicon germanium (SiGe).

4. The semiconductor storage device according to claim 1, wherein the hafnium oxide film includes yttrium (Y) elements such that an atomicity ratio satisfies 0.007≦(Hf+Y)≦0.06.

5. The semiconductor storage device according to claim 1, wherein the oxide film comprises either a silicon oxynitride a germanium oxynitride film, or a silicon germanium oxynitride film.

6. The semiconductor storage device according to claim 1, wherein the hafnium oxide film having the orthorhombic phase III structure possesses ferroelectricity.

7. A semiconductor storage device comprising:
a semiconductor channel region;
a first insulating layer including an oxide film disposed in contact with the semiconductor channel region, an yttrium oxide containing film disposed on the oxide film, and a hafnium oxide film disposed on the yttrium oxide containing film; and
a control electrode disposed on the first insulating laver.

8. The semiconductor storage device according to claim 7, wherein the semiconductor channel region comprises silicon.

9. The semiconductor storage device according to claim 7, wherein the semiconductor channel region comprises either germanium (Ge) or silicon germanium (SiGe).

10. The semiconductor storage device according to claim 7, wherein the hafnium oxide film includes yttrium (Y) elements such that an atomicity ratio satisfies 0.001≦Y/(Hf+Y)≦0.06.

11. The semiconductor storage device according to claim 7, wherein the oxide film comprises either a silicon oxynitride film, a germanium oxynitride film, or a silicon germanium oxynitride film.

12. The semiconductor storage device according to claim 7, wherein the hafnium oxide film possesses ferroelectricity.

13. A semiconductor storage device comprising:
a semiconductor channel region;
a first insulating layer including an oxide film disposed in contact with the semiconductor channel region, an yttrium oxide containing film disposed on the oxide film, and a hafnium oxide film disposed on the yttrium oxide containing film; and
a control electrode disposed on the first insulating layer, the hafnium oxide film being configured to satisfy at least either of:
including silicon (Si) elements such that an atomicity ratio satisfies 0.02≦Si/(Hf+Si)≦0.05,
including yttrium (Y) elements such that an atomicity ratio satisfies 0.001≦Y/(Hf+Y)≦0.06,
including aluminum (Al) elements such that an atomicity ratio satisfies 0.04≦Al(Hf+Al)≦0.1, and
including zirconium (Zr) elements such that an atomicity ratio satisfies 0.3≦Zr/(Hf+Zr)≦0.7.

14. The semiconductor storage device according to claim 13, wherein the semiconductor channel region comprises silicon.

15. The semiconductor storage device according to claim 13, wherein the semiconductor channel region comprises either germanium (Ge) or silicon germanium (SiGe).

16. The semiconductor storage device according to claim 13, wherein the oxide film comprises either a silicon oxynitride film, a germanium oxynitride film, or silicon icon germanium oxynitride film.

17. The semiconductor storage device according to claim 13, wherein the hafnium oxide film has an orthorhombic phase III structure.

18. The semiconductor storage device according to claim 17, wherein the hafnium oxide film having the orthorhombic phase in structure possesses ferroelectricity.
